(19) United States
(12) Patent Application Publication
(10) Pub. No.: US 2025/0234630 A1
(43) Pub. Date: Jul. 17, 2025

(54) POWER SEMICONDUCTOR DEVICE

(71) Applicant: SAMSUNG ELECTRONICS CO., LTD., Suwon-si (KR)

(72) Inventors: Taehun Kim, Suwon-si (KR); Mingu Ko, Suwon-si (KR); Gyeongseon Park, Suwon-si (KR); Youngcheol Kim, Suwon-si (KR); Jongseob Kim, Suwon-si (KR); Jeongin Noh, Suwon-si (KR)

(21) Appl. No.: 18/886,654

(22) Filed: Sep. 16, 2024

(30) Foreign Application Priority Data
Jan. 11, 2024 (KR) 10-2024-0004655

(51) Int. Cl. H01L 29/51; H01L 29/16; H01L 29/423; H01L 29/78

(52) U.S. Cl. CPC H10D 64/683; H10D 30/668; H10D 64/513; H10D 64/516; H10D 62/8325

(57) ABSTRACT

A power semiconductor device includes a substrate of a first conductivity type, a drift layer of a first conductivity type on the substrate, a well region of a second conductivity type on the drift layer, a source region of the first conductivity type on the well region, a gate electrode disposed in a gate trench penetrating through the source region and the well region, a first gate insulating layer, a second gate insulating layer, and a third gate insulating layer sequentially disposed between the well region and the gate electrode, a dielectric layer on the gate electrode, and a drain electrode on a lower surface of the substrate.

### CROSS-REFERENCE TO RELATED APPLICATION(S)

This application claims the benefit under 35 USC 119(a) of Korean Patent Application No. 10-2024-0004655, filed in the Korean Intellectual Property Office on Jan. 11, 2024, the disclosure of which is incorporated by reference herein in its entirety.

### BACKGROUND

Power semiconductor devices are semiconductor devices operating in high voltage and high current environments and are used in fields requiring high power switching, such as power conversion, power converters, inverters, and the like. Power semiconductor devices basically require voltage resistance characteristics against high voltages, and recently, have additionally required high-speed switching operations. Accordingly, research into power semiconductor devices using SiC having superior voltage resistance characteristics compared to silicon (Si) is being undertaken.

### SUMMARY

In general, in some aspects, the present disclosure is directed toward a power semiconductor device having improved electrical characteristics.

According to some implementations, the present disclosure is directed to a power semiconductor device that includes a substrate of a first conductivity type; a drift layer of a first conductivity type on the substrate; a well region of a second conductivity type on the drift layer; a source region of the first conductivity type on the well region; a gate electrode disposed in a gate trench penetrating through the source region and the well region; a first gate insulating layer, a second gate insulating layer, and a third gate insulating layer sequentially disposed between the well region and the gate electrode; a dielectric layer on the gate electrode; and a drain electrode on a lower surface of the substrate. The first gate insulating layer has a first dielectric constant. The second gate insulating layer has a second dielectric constant, greater than the first dielectric constant. The third gate insulating layer has a first thickness on a bottom surface of the gate trench and a second thickness, less than the first thickness, on a sidewall of the gate trench.

According to some implementations, the present disclosure is directed to a power semiconductor device that includes a substrate of a first conductivity type; a drift layer of a first conductivity type on the substrate; a well region of a second conductivity type on the drift layer; a source region of the first conductivity type on the well region; a gate electrode in a gate trench penetrating through the source region and the well region; gate insulating layers including a first gate insulating layer, a second gate insulating layer, and a third gate insulating layer sequentially disposed between the well region and the gate electrode; a dielectric layer on the gate electrode; and a drain electrode on a lower surface of the substrate. The second gate insulating layer includes an insulating material different from insulating materials of the first and third gate insulating layers. The gate insulating layers have a first thickness on a bottom surface of the gate trench and a second thickness, less than the first thickness, on a sidewall of the gate trench.

According to some implementations, the present disclosure is directed to a power semiconductor device that includes a substrate of a first conductivity type; a drift layer of a first conductivity type on the substrate; a well region of a second conductivity type on the drift layer; a source region of the first conductivity type on the well region; a gate electrode in a gate trench penetrating through the source region and the well region; gate insulating layers disposed between the well region and the gate electrode, having a first thickness on a bottom surface of the gate trench and a second thickness, less than the first thickness, on a sidewall of the gate trench; a dielectric layer on the gate electrode; and a drain electrode on a lower surface of the substrate. The gate insulating layers includes a first gate insulating layer on the sidewall of the gate trench; a second gate insulating layer on the first gate insulating layer; and a third gate insulating layer disposed on the second gate insulating layer and in contact with the gate electrode. The third gate insulating layer has a third thickness on the bottom surface of the gate trench and a fourth thickness less than the third thickness on the sidewall of the gate trench.

### BRIEF DESCRIPTION OF DRAWINGS

Example implementations will be more clearly understood from the following detailed description, taken in conjunction with the accompanying drawings.

FIG. 1A is a cross-sectional view of an example of a power semiconductor device according to some implementations.

FIG. 1B is an enlarged view of an example of a region A of the power semiconductor device of FIG. 1 according to some implementations.

FIG. 2A is a cross-sectional view of an example of a power semiconductor device according to some implementations.

FIG. 2B is an enlarged view of an example of a region B of the power semiconductor device of FIG. 2A according to some implementations.

FIG. 2C is a cross-sectional view of an example of a power semiconductor device according to some implementations.

FIGS. 3A and 3B are cross-sectional views of an examples of a power semiconductor device according to some implementations.

FIG. 4 is a cross-sectional view of an example of a power semiconductor device according to some implementations.

FIGS. 5 to 11 are diagrams illustrating an example of a method of manufacturing the power semiconductor device of FIG. 1A according to some implementations.

### DETAILED DESCRIPTION

Hereinafter, example implementations will be explained in detail with reference to the accompanying drawings. The same reference numerals are used for the same components in the drawings, and duplicate descriptions for the same components are omitted.

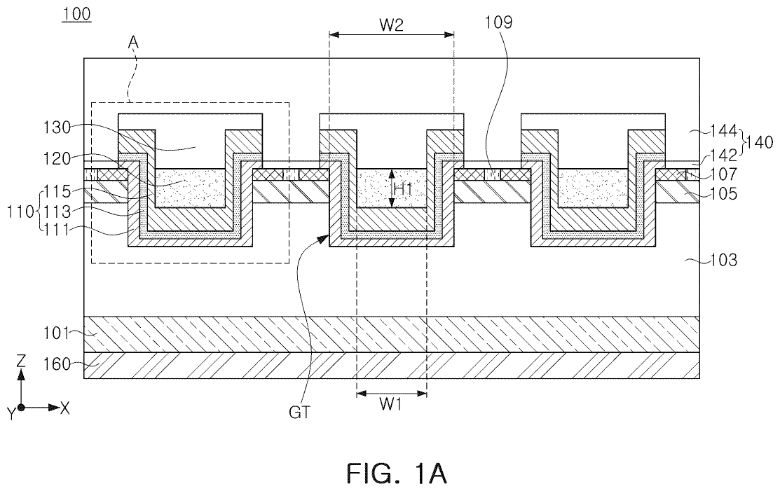

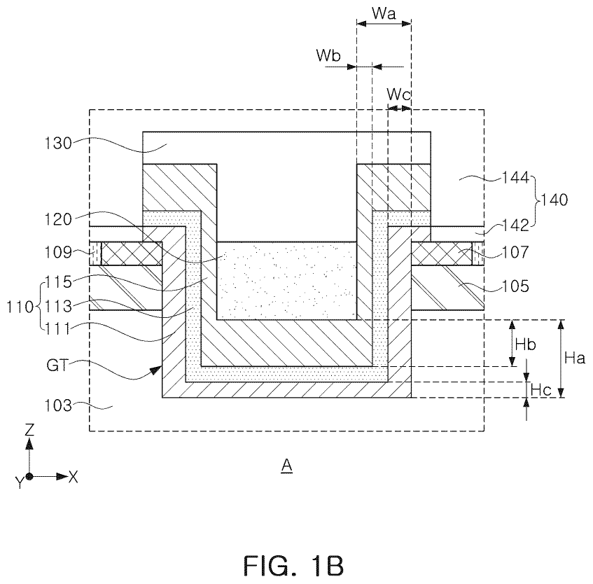

FIG. 1A is a cross-sectional view of an example of a power semiconductor device according to some implementations. In FIG. 1A, a power semiconductor device 100 may include a substrate 101, a drift layer 103 on the substrate 101, well regions 105 disposed on the drift layer 103, source regions 107 disposed on the well region 105, well contact regions 109 on one side of the source regions 107, gate electrodes 120 disposed in gate trenches GT penetrating through the well region 105 and the source regions 107, gate insulating layers 110 between the gate electrodes 120 and the well region 105, dielectric layers 130 covering the gate electrodes 120, a source electrode 140 on the dielectric layers 130, and a drain electrode 160 on the lower surface of the substrate 101.

The substrate 101 may include an upper surface extending in a first direction (X-direction) and a second direction (Y-direction). The substrate 101 may include a semiconductor material. The semiconductor material may include silicon carbide (SiC). However, the present disclosure is not limited thereto. In another example, the substrate 101 may include a group IV semiconductor material, such as silicon (Si), germanium (Ge), tin (Sn), or a compound semiconductor material, such as SiGe, GaAs, InAs, or InP.

The substrate 101 may be provided as a bulk wafer or an epitaxial layer. The substrate 101 may include first conductivity type impurities and may have a first conductivity type. In some implementations, the first conductivity type may be N-type, and the first conductivity type impurities may be N-type impurities, such as nitrogen (N) and/or phosphorus (P). In some implementations, the first conductivity type may be P-type, and the first conductivity type impurities may be P-type, such as aluminum (Al).

The drift layer 103 may be disposed on the substrate 101. The drift layer 103 may include a semiconductor material. The semiconductor material may include silicon carbide (SIC). The drift layer 103 may be an epitaxial layer grown on the substrate 101. The drift layer 103 may include first conductive impurities and thus may have a first conductivity type. In some implementations, the concentration of the first conductivity type impurities in the drift layer 103 may be lower than the concentration of the first conductivity type impurities in the substrate 101. In some implementations, the first conductivity type impurities in the substrate 101 and the drift layer 103 may include the same or different elements.

The well regions 105 may be disposed at a predetermined depth from the upper surface of the drift layer 103. In some implementations, the well regions 105 may be arranged to be spaced apart from each other by the gate trench GT in the first direction (X-direction). Well region 105 may include a semiconductor material. The semiconductor material may include silicon carbide (SiC). The well region 105 may include second conductivity type impurities, and accordingly, may have a second conductivity type. The second conductivity type may be P-type, and the second conductivity type impurities may be P-type impurities such as aluminum (Al). In some implementations, well region 105 may include multiple regions with different doping.

The source regions 107 may be disposed at a predetermined depth from the upper surfaces of the well regions 105. The thickness of the source regions 107 may be smaller than the thickness of the well region 105. The source region 107 may include a semiconductor material. The semiconductor material may include silicon carbide (SiC). The source region 107 may include the first conductivity type impurities, and accordingly, may have the first conductivity type. In some implementations, the concentration of first conductivity type impurities in the source region 107 may be higher than the concentration of first conductivity type impurities in the drift layer 103, but is not limited thereto.

The well contact regions 109 may be disposed on the well regions 105 between adjacent source regions 107. The well contact regions 109 may be disposed between the well region 105 and the source regions 107 to allow the voltage from the source electrode 140 to be applied to the well region 105. The well contact regions 109 may include a semiconductor material, for example, SiC. The well contact region 109 may be a region having the second conductivity type, and may include the second conductivity type impurities described above. The concentration of second conductivity type impurities in the well contact region 109 may be higher than the concentration of second conductivity type impurities in the well region 105.

The gate trenches GT may extend from the upper surfaces of the source regions 107 through the source regions 107 and the well regions 105 into the drift layer 103. The gate trench GT may completely penetrate the well region 105, and a lower end of the gate trench GT may be located within the drift layer 103. However, the length of the gate trench GT extending into the drift layer 103 may change according to some implementations. For example, a lower end of the gate trench GT may be located on the upper surface of the drift layer 103.

The gate trench GT may include a sidewall extending in the vertical direction (Z-direction) and contacting the source regions 107, the well regions 105, and the drift layer 103, and a bottom surface extending from the sidewall in the first direction (X-direction) and in contact with the drift layer 103. In some implementations, the gate trench GT may include a sidewall in contact with the source regions 107 and the well regions 105, and a bottom surface extending from the sidewall in a first direction (X-direction) and in contact with the well regions 105.

The gate trench GT may have an angular shape without curves. The angle between the sidewall and bottom surface of the gate trench GT may be a right angle. In some implementations, the sidewall of the gate trench GT may have a side extending vertically, and the width of the gate trench GT may be substantially constant. However, the present disclosure is not limited thereto. In some implementations, the angle between the sidewall and the bottom surface of the gate trench GT may be an obtuse angle. In this case, the sidewall of the gate trench GT may have an inclined side, and the width of the gate trench GT may become smaller toward the lower part of the gate trench GT. In some implementations, the bottom surface of the gate trench GT may extend substantially in a straight line in the first direction (X-direction). However, the present disclosure is not limited thereto, and the shape of the gate trench GT may be modified in various manners.

The gate electrodes 120 may each be disposed within the gate trench GT. The gate electrode 120 may be disposed on the gate insulating layers 110 within the gate trench GT. In some implementations, the gate electrode 120 may overlap the gate insulating layers 110, the drift layer 103, the well region 105, and the source region 107 in the first direction (X-direction) (or horizontal direction). The lower surface of the gate electrode 120 may be located within the drift layer 103. The lower surface of the gate electrode 120 may be located at a lower level than the lower surface of the well region 105, and the upper surface of the gate electrode 120 may be located at a lower level than the upper surface of the source region 107. However, the present disclosure is not limited thereto. For example, the upper surface of the gate electrode 120 may be located at the same level as the upper surface of the source region 107.

The gate electrode 120 may include a side surface having a shape corresponding to the sidewall of the gate trench GT, an upper surface extending from the side surface in a first direction (X-direction) and in contact with the dielectric layer 130, and a lower surface facing the upper surface and in contact with the third gate insulating layer 115. In some implementations, a side surface of the gate electrode 120 may be perpendicular to the substrate 101. However, the present disclosure is not limited thereto, and the side of the gate electrode 120 may have an inclined side with respect to the substrate 101. In some implementations, the lower surface of the gate electrode 120 may correspond to the shape of the upper surface of the third gate insulating layer 115, which is described below.

The gate electrode 120 may have a first width W1 in the first direction (X-direction) and a first height H1 in the third direction (Y-direction). In some implementations, the first width W1 may be greater than the first height H1. In some implementations, the first width W1 may be smaller than the second width W2 in the first direction (X-direction) of the gate trench GT.

The gate electrode 120 may include a conductive material, and the conductive material may include a semiconductor material, such as doped polycrystalline silicon, a metal nitride, such as titanium nitride (TiN), tantalum nitride (TaN), or tungsten nitride (WN), and/or a metallic material, such as aluminum (Al), tungsten (W), or molybdenum (Mo).

The gate insulating layers 110 may be disposed within the gate trench GT. Gate insulating layers 110 may cover the side and bottom surfaces of the gate electrode 120. In some implementations, the gate insulating layers 110 may be disposed between the source region 107, the well contact region 109, the well region 105, and the drift layer 103 and the gate electrode 120. The gate insulating layers 110 may include a plurality of gate insulating layers 111, 113, and 115. The plurality of gate insulating layers 111, 113, and 115 may include a first gate insulating layer 111, a second gate insulating layer 113 on the first gate insulating layer 111, and a third gate insulating layer 115 on the second gate insulating layer 113, sequentially disposed within the gate trench GT.

The first gate insulating layer 111 may be disposed on the source region 107, the well region 105, and the drift layer 103 within the gate trench GT. In some implementations, the first gate insulating layer 111 may be disposed according to the surface profile of the gate trench GT.

The first gate insulating layer 111 may include a first insulating material. For example, the first insulating material may include oxide or nitride. For example, the first gate insulating layer 111 may include a silicon oxide layer (SiO₂). In some implementations, the first gate insulating layer 111 may be formed through a thermal oxidation process. The thermal oxidation process may use at least one plasma from among oxygen (O₂), water (H₂O), and ozone (O₃).

The second gate insulating layer 113 may be disposed on the first gate insulating layer 111. The second gate insulating layer 113 may be disposed according to the surface profile of the first gate insulating layer 111.

The second gate insulating layer 113 may include a second insulating material. The second insulating material may include a material different from the insulating materials of the first and third gate insulating layers 111 and 115. In some implementations, the second gate insulating layer 113 may include a high-κ material. The high-κ material may refer to a dielectric material having a higher dielectric constant than a silicon oxide film (SiO₂). The high-κ material may be any one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). In some implementations, the second gate insulating layer 113 may include a ferromagnetic material. For example, the second gate insulating layer 113 may include metals, such as iron (Fe), nickel (Ni), cobalt (Co), and combinations thereof, but is not limited thereto. In some implementations, the second gate insulating layer 113 may be deposited by an atomic layer deposition (ALD) process.

The dielectric constant of the second gate insulating layer 113 (hereinafter referred to as second dielectric constant) may have a dielectric constant greater than the dielectric constant of the first and third gate insulating layers 111 and 115 (hereinafter referred to as first dielectric constant).

The third gate insulating layer 115 may be disposed on the second gate insulating layer 113. The third gate insulating layer 115 may include a lower surface in contact with the second gate insulating layer 113 and an upper surface in contact with the side and bottom surfaces of the gate electrode 120. In some implementations, the lower surface of the third gate insulating layer 115 may have a shape corresponding to the surface profile of the second gate insulating layer 113. The upper surface of the third gate insulating layer 115 may include a first surface corresponding to the sidewall of the gate trench GT, a second surface extending from the first surface toward the bottom surface of the gate trench GT, and a third surface extending from the first surface toward the source electrode 140. In an example, the second surface extending from the first surface toward the bottom surface of the gate trench GT may include a flat surface parallel to the first direction (X-direction). The second surface of the third gate insulating layer 115 may overlap the lower surface of the gate electrode 120 in the vertical direction (Z-direction). In some implementations, the vertical thickness of the third surface of the third gate insulating layer 115 may be substantially the same as the vertical thickness of the second surface of the third gate insulating layer 115. However, the present disclosure is not limited thereto, and the vertical thickness of the third surface of the third gate insulating layer 115 may be smaller than the vertical thickness of the second surface of the third gate insulating layer 115.

The third gate insulating layer 115 may include a third insulating material. The third insulating material may include oxide and/or nitride. In some implementations, the third gate insulating layer 115 may be deposited using deposition techniques, such as chemical vapor deposition (CVD), plasma enhanced chemical deposition (PE-CVD), or spin on dielectric (SOD). The third insulating material may be the same as the first insulating material included in the first gate insulating layer 111. However, the third insulating material is not limited thereto, and may include an insulating material that is different from the first insulating material of the first gate insulating layer 111.

The first, second, and third gate insulating layers 111, 113, and 115 may cover the side and bottom surfaces of the gate electrode 120. The gate electrode 120 may overlap the first, second, and third gate insulating layers 111, 113, and 115 in the horizontal direction (X-direction) and the vertical direction (Z-direction).

The gate insulating layers 110 may extend from the inner surface of the gate trench GT and be disposed on the source region 107 that is the outer surface of the gate trench GT. The first gate insulating layer 111, the second gate insulating layer 113, and the third gate insulating layer 115 may extend from the sidewalls of the gate trench GT and be sequentially disposed on a portion of source region 107 in the vertical direction (Z-direction).

The first and second gate insulating layers 111 and 113 may have an angled surface profile corresponding to the surface shape of the gate trench GT.

The lower and upper surfaces of the third gate insulating layer 115 may have an angled surface profile. In some implementations, the lower surface of the third gate insulating layer 115 may have a surface profile corresponding to the surface shape of the gate trench GT. The upper surface of the third gate insulating layer 115 may have a surface profile corresponding to the side and bottom surfaces of the gate electrode 120 within the gate trench GT. In some implementations, a portion of the upper surface of the third gate insulating layer 115 that is in contact with the lower surface of the gate electrode 120 may include a flat surface substantially parallel to the first direction (X-direction).

The dielectric layers 130 may cover the gate electrodes 120 and may be arranged to expose portions of each of the well regions 105 and source regions 107 and the well contact regions 109. The dielectric layer 130 may cover the gate insulating layers 110 disposed on the upper surface of the gate electrode 120 and one region of the source region 107. In some implementations, the dielectric layer 130 may include an insulating material and may include at least one of silicon oxide, silicon nitride, and silicon oxynitride. For example, the dielectric layer 130 may include phosphosilicate glass (PSG) or borophosphosilicate glass (BPSG).

The source electrode 140 may be disposed on the dielectric layer 130 and electrically connected to the source regions 107 and the well contact regions 109. The source electrode 140 may also be electrically connected to the well regions 105 in some areas. The source electrode 140 may include a metal-semiconductor compound layer 142 and a conductive layer 144. The metal-semiconductor compound layer 142 may include a metal element and a semiconductor element, and for example, may include at least one of TiSi, CoSi, MoSi, LaSi, NiSi, TaSi, or Wsi. The conductive layer 144 is formed of a metal material, and for example, may contain at least one of nickel (Ni), aluminum (Al), titanium (Ti), silver (Ag), vanadium (V), tungsten (W), cobalt (Co), molybdenum (Mo), copper (Cu), titanium. nitride (TiN), and ruthenium (Ru).

The drain electrode 160 may be disposed on the lower surface of the substrate 101 and electrically connected to the substrate 101. The drain electrode 160 may include at least one of a metal material, for example, nickel (Ni), aluminum (Al), titanium (Ti), silver (Ag), vanadium (V), and tungsten (W). In some implementations, the drain electrode 160 may also include a metal-semiconductor compound layer and a conductive layer, similar to the source electrode 140.

FIG. 1B is an enlarged view of an example of a region A of the power semiconductor device of FIG. 1A according to some implementations. In FIG. 1B, the gate insulating layers 110 may have non-uniform thickness. The gate insulating layers 110 may have a first thickness Ha on the bottom surface of the gate trench GT and a second thickness Wa that is smaller than the first thickness Ha on the sidewalls of the gate trench GT. In some implementations, the first thickness Ha may be a vertical length from the lower surface of the gate electrode 120 to the bottom surface of the gate trench GT. The second thickness Wa may be the horizontal length from the side of the gate electrode 120 to the well region 105.

The third gate insulating layer 115 may have a non-uniform thickness. The third gate insulating layer 115 may have a third thickness Hb on the bottom surface of the gate trench GT, and a fourth thickness Wb smaller than the third thickness Hb on the side surface of the gate trench GT. In some implementations, the third thickness Hb may be a vertical length from the bottom surface of the gate electrode 120 to the bottom surface of the third gate insulating layer 115 adjacent to the bottom surface of the gate trench GT. The fourth thickness Wb may be the horizontal length from the side of the gate electrode 120 to the outer surface of the third gate insulating layer 115 adjacent to the sidewall of the gate trench GT.

The first gate insulating layer 111 may have a non-uniform thickness. The first gate insulating layer 111 may have a fifth thickness Hc on the bottom surface of the gate trench GT and a sixth thickness Wc greater than the fifth thickness Hc on the sidewall of the gate trench GT. In an example, the fifth thickness Hc may be a vertical length from the top surface of the first gate insulating layer 111 that overlaps the gate electrode 120 in the vertical direction to the bottom surface of the gate trench GT. The sixth thickness Wc may be the horizontal length from the upper surface of the first gate insulating layer 111 that overlaps the gate electrode 120 in the horizontal direction to the well region 105. In some implementations, the fifth thickness Hc and the sixth thickness Wc may be the same.

The second gate insulating layer 113 may have a substantially constant thickness. The second gate insulating layer 113 may be disposed conformally along the surface profile of the first gate insulating layer 111.

According to some implementations, the gate insulating layers 110 have a relatively large thickness on the bottom surface of the gate trench GT, so that the electric field concentrated on the edge or bottom surface of the gate trench GT by the gate electrode 120 may be alleviated. Accordingly, the power semiconductor device 100 may prevent the gate insulating layers 110 from being destroyed by the electric field concentrated on the edge or bottom surface of the gate trench GT, thereby providing improved power reliability.

In the present disclosure, descriptions that overlap with those described above with reference to FIGS. 1A and 1B will be omitted.

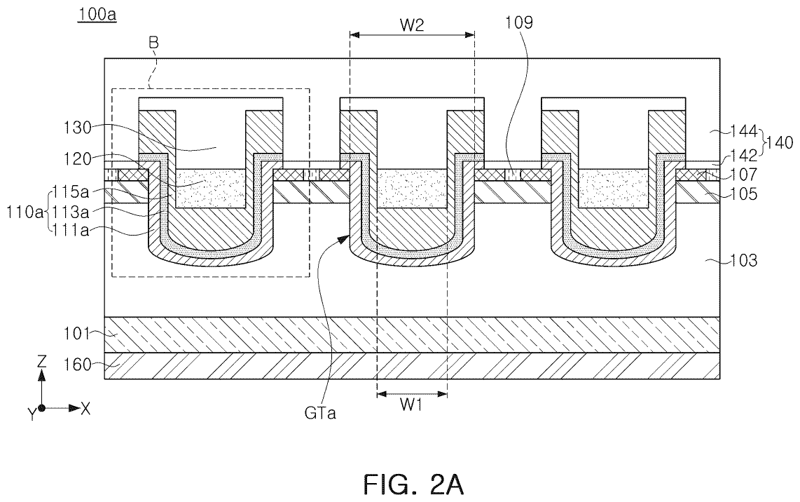

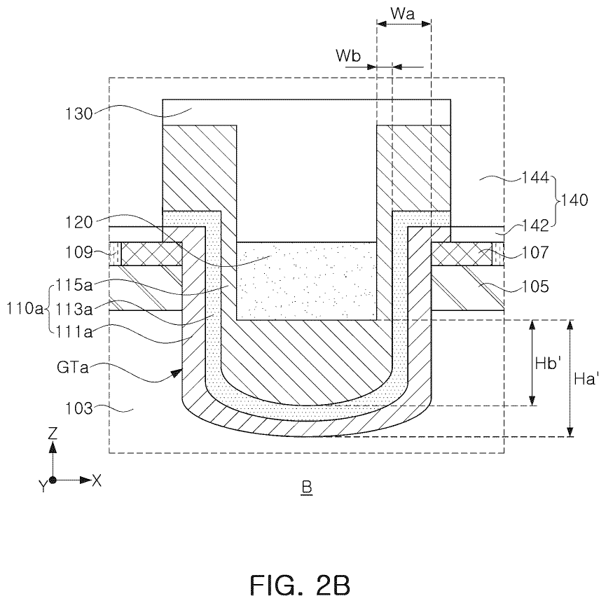

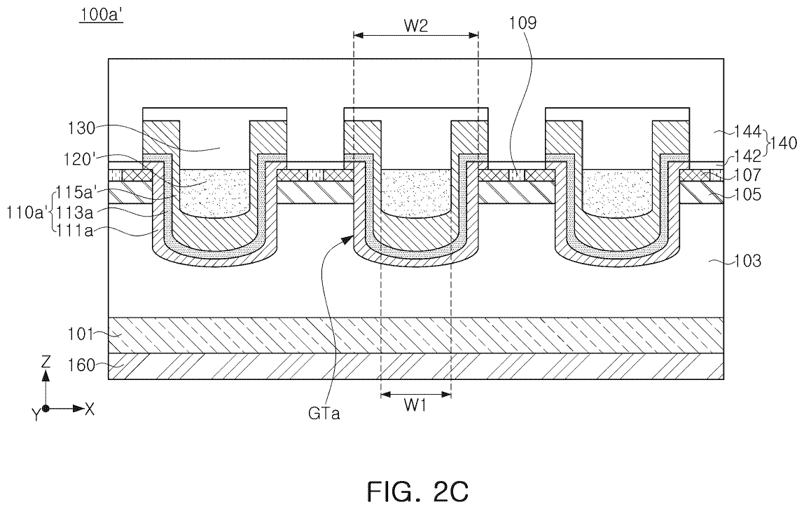

FIG. 2A is a cross-sectional view of an example of a power semiconductor device according to some implementations. FIG. 2B is an enlarged view of an example of a region B of the power semiconductor device of FIG. 2A according to some implementations. In FIGS. 2A and 2B, configurations of a power semiconductor device 100a, except for the gate trench GTa and gate insulating layers 110a, may be the same or similar to the configurations of the power semiconductor device 100 of FIG. 1A.

In FIGS. 2A and 2B, the gate trench GTa is smoothed and may have a curved shape in which the angle of the inner surface is relaxed. The gate trench GTa may have a sidewall extending in the vertical direction (Z-direction) and in contact with the source regions 107, the well regions 105, and the drift layer 103, and a bottom surface extending from the sidewall in the first direction (X-direction) and in contact with the drift layer 103. The sidewall of the gate trench GTa may have a side extending vertically, and the bottom surface of the gate trench GTa may extend from the sidewall and be convex toward the substrate 101. In some implementations, the width of the gate trench GTa may become smaller toward the bottom. In some implementations, the sidewall of the gate trench GTa may be non-linearly extended and connected to the bottom surface of the gate trench GTa.

The gate insulating layers 110a may be disposed within the gate trench GTa. The gate insulating layers 110a may be disposed between the side and bottom surfaces of the gate electrode 120 on the inner surface of the gate trench GTa. In some implementations, the gate insulating layers 110a may be disposed between the source region 107, the well region 105, and the drift layer 103 and the gate electrode 120.

The first and second gate insulating layers 111a and 113a may have a curved surface profile corresponding to the surface shape of the gate trench GTa.

The lower surface of the third gate insulating layer 115a may have a curved surface profile according to the shape of the gate trench GTa. The upper surface of the third gate insulating layer 115a may have a surface profile different from the lower surface of the third gate insulating layer 115a. The upper surface of the third gate insulating layer 115a may include a first surface corresponding to the sidewall of the gate trench GTa, a second surface extending from the first surface toward the bottom surface of the gate trench GTa, and a third surface extending from the first surface toward the source electrode 140. In some implementations, the second surface extending from the first surface toward the bottom surface of the gate trench GTa may include a horizontal surface parallel to the first direction (X-direction).

In FIG. 2B, the gate insulating layers 110a may have non-uniform thickness. The gate insulating layers 110a may have a first thickness Ha′ on the bottom surface of the gate trench GTa and a second thickness Wa less than the first thickness Ha′ on the sidewalls of the gate trench GTa. In an example, the first thickness Ha′ may be a vertical length from the bottom surface of the gate electrode 120 to the lowest level of the bottom surface of the gate trench GTa. The second thickness Wa may be a horizontal length from the side of the gate electrode 120 to the well region 105.

The third gate insulating layer 115a may have a non-uniform thickness. The third gate insulating layer 115a may have a third thickness Hb′ on the bottom surface of the gate trench GTa and a fourth thickness Wb that is smaller than the third thickness Hb′ on the side surface of the gate. The third thickness Hb′ may be a vertical length from the bottom surface of the gate electrode 120 to the lowest level of the third gate insulating layer 115a. The fourth thickness Wb may be the horizontal length from the side of the gate electrode 120 to the lower surface of the third gate insulating layer 115a adjacent to the side of the gate trench GTa.

FIG. 2C is a cross-sectional view of an example of a power semiconductor device according to some implementations. In FIG. 2C, the configuration of the power semiconductor device 100a′, except for the gate electrode 120′ and the gate insulating layers 110a′, may be the same or similar to the configurations of the power semiconductor device 100a of FIG. 2A.

In FIG. 2C, the lower and upper surfaces of the third gate insulating layer 115a′ may have the same surface profile. The lower and upper surfaces of the third gate insulating layer 115a′ may have a curved surface profile according to the shape of the gate trench GTa.

The gate electrode 120′ may be disposed within the gate trench GTa where the third gate insulating layer 115a′ is disposed. The gate electrode 120′ may have a lower surface curved to correspond to the upper surface of the third gate insulating layer 115a′.

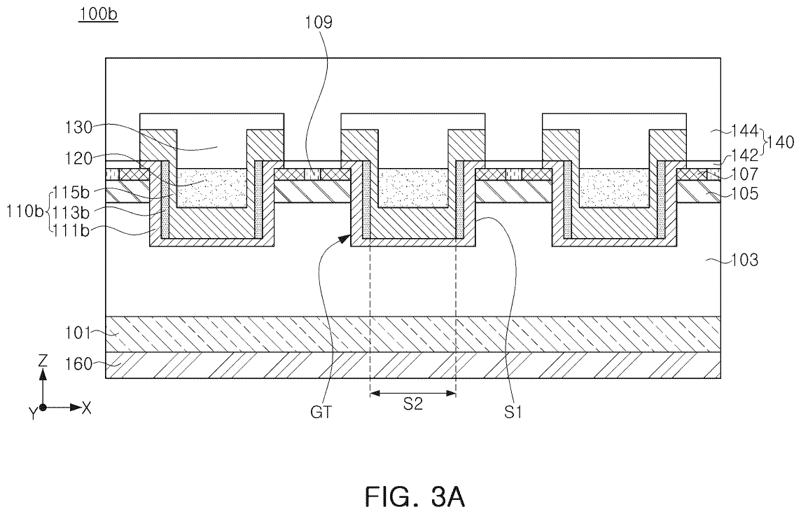

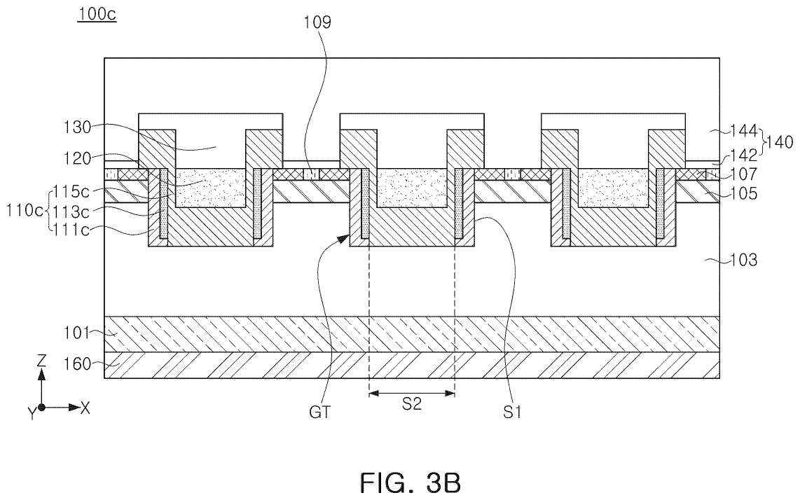

FIG. 3A is a cross-sectional view of an example of a power semiconductor device according to some implementations. In FIG. 3A, the configuration of a power semiconductor device 100b, except for the gate insulating layers 110b, may be the same or similar to the configurations of the power semiconductor device 100 of FIG. 1A.

In FIG. 3A, the gate insulating layers 110b may be disposed within the gate trench GT. The gate insulating layers 110b may be disposed between the side and bottom surfaces of the gate electrode 120 on the inner surface of the gate trench GT. In some implementations, the gate insulating layers 110b may be disposed between the source region 107, the well region 105, and the drift layer 103 and the gate electrode 120.

The gate insulating layers 110b may include a plurality of gate insulating layers 111b, 113b, and 115b. The plurality of gate insulating layers 111b, 113b, and 115b may include a first gate insulating layer 111b, a second gate insulating layer 113b, and a third gate insulating layer 115b disposed in the gate trench GT.

The gate electrode 120 may overlap a plurality of gate insulating layers 111b, 113b, and 115b in the horizontal direction (X-direction). The gate electrode 120 may overlap the first and third gate insulating layers 111b and 115b in the vertical direction (Z-direction) and may not overlap the second gate insulating layer 113b.

The first gate insulating layer 111b may be disposed on the source region 107, the well region 105, and the drift layer 103 within the gate trench GT. In an example, the first gate insulating layer 111 may be disposed according to the surface profile of the gate trench GT.

The second gate insulating layer 113b may be disposed on the first gate insulating layer 111b. The second gate insulating layer 113b may be disposed only on the first gate insulating layer 111b disposed on the sidewall S1 of the gate trench GT. The second gate insulating layer 113b may not be disposed on the bottom surface S2 of the gate trench GT. In an example, the second gate insulating layer 113b may not be disposed on the source electrode 140.

In the case of the second gate insulating layer 113b, the second gate insulating layer, such as the second gate insulating layer 113 in FIG. 1A, is disposed according to the surface profile of the first gate insulating layer 111b, and then, a portion of the second gate insulating layer 113 corresponding to the bottom surface S2 of the gate trench GT is removed through an etch-back process, thereby forming of the second gate insulating layer 113b. A portion of the second gate insulating layer 113 extending onto the source electrode 140 may also be removed through the etch-back process.

The third gate insulating layer 115b may be disposed on the first gate insulating layer 111b and the second gate insulating layer 113b. The third gate insulating layer 115b may be disposed on the first gate insulating layer 111b exposed on the bottom surface S2 of the gate trench GT and the second gate insulating layer 113 on the sidewall S1 of the gate trench GT. The third gate insulating layer 115b may contact the first gate insulating layer 111b disposed on the bottom surface S2 of the gate trench GT. The third gate insulating layer 115c may overlap the first gate insulating layer 111c in the vertical direction (Z-direction) within the gate trench GT, and may not overlap the second gate insulating layer 113c. In some implementations, the third gate insulating layer 115b may be disposed on the first gate insulating layer 111b extending onto the source electrode 140.

The gate insulating layers 110b have a relatively large thickness on the bottom surface S2 of the gate trench GT. The electric field concentrated on the edge or bottom surface S2 of the gate trench GT may be alleviated by the gate electrode 120.

The thickness of the gate insulating layer 110b on the bottom surface of the gate trench GT may be thicker than the thickness of the gate insulating layer 110b on the sidewall of the gate trench GT. In an example, the thickness of the third gate insulating layer 115b on the bottom surface of the gate trench GT may be thicker than the thickness of the third gate insulating layer 115b on the sidewall of the gate trench GT. The thickness of the gate insulating layer 110b on the sidewall of the gate trench GT may be equal to the sum of the thicknesses of the first, second, and third gate insulating layers 111b, 113b, and 115b on the sidewall of the gate trench GT. The thickness of the gate insulating layer 110b on the bottom surface of the gate trench GT may be equal to the sum of the thicknesses of the first and third gate insulating layers 111b and 115b on the bottom surface of the gate trench GT.

The power semiconductor device 100b may include a second gate insulating layer 113b having a high dielectric constant on the sidewall of the gate trench GT and disposed between the first and third gate insulating layers 111b and 115b, a first gate insulating layer 111b having a dielectric constant relatively lower than that of the second gate insulating layer 113b on the bottom surface S2 of the gate trench GT, and a third gate insulating layer 115b disposed directly on the first gate insulating layer 111b. Accordingly, the power semiconductor device 100b may relatively reduce the size of the parasitic capacitor, thereby providing a semiconductor device with improved reliability.

FIG. 3B is a cross-sectional view of an example of a power semiconductor device according to some implementations. In FIG. 3B, the configuration of the power semiconductor device 100c, except for the gate insulating layers 110c, may be the same or similar to the configurations of the power semiconductor device 100 of FIG. 1A.

In FIG. 3B, the gate insulating layers 110c may include a plurality of gate insulating layers 111c, 113c, and 115c. The plurality of gate insulating layers 111c, 113c, and 115c may include a first gate insulating layer 111c, a second gate insulating layer 113c, and a third gate insulating layer 115c disposed in the gate trench GT.

The gate electrode 120 may overlap a plurality of gate insulating layers 111c, 113c, and 115c in the horizontal direction (X-direction). The gate electrode 120 may overlap the third gate insulating layer 115c in the vertical direction (Z-direction) and may not overlap the first and second gate insulating layers 111c and 113c.

The first gate insulating layer 111c may be disposed on the source region 107 and the sidewall S1 of the gate trench GT. The first gate insulating layer 111c may be disposed according to the surface profile of the sidewall S1 of the gate trench GT. The first gate insulating layer 111c may not be disposed on the bottom surface S2 of the gate trench GT. In some implementations, the first gate insulating layer 111c may not be disposed on the source electrode 140.

The second gate insulating layer 113c may be disposed on the first gate insulating layer 111c. The second gate insulating layer 113c may be disposed on the first gate insulating layer 111c disposed on the source region 107 and the sidewall S1 of the gate trench GT. The second gate insulating layer 113c may not be disposed on the bottom surface S2 of the gate trench GT. In some implementations, the second gate insulating layer 113c may not be disposed on the source electrode 140.

In the case of the first and second gate insulating layers 111c and 113c, the first and second gate insulating layers, such as the first and second gate insulating layers 111 and 113 in FIG. 1A, are sequentially disposed according to the surface profile of the gate trench GT, and then, portions of the first and second gate insulating layers 111 and 113 corresponding to the bottom surface S2 of the gate trench GT are removed through an etch-back process, thereby forming the first and second gate insulating layers 111c and 113c. Parts of the first and second gate insulating layers 111 and 113 extending onto the source electrode 140 may also be removed through the etch-back process.

The third gate insulating layer 115c may be disposed on the second gate insulating layer 113c and the bottom surface S2 of the gate trench GT. The third gate insulating layer 115c may be disposed on the second gate insulating layer 113c disposed on the sidewall S1 of the gate trench GT and on the drift layer 103 exposed through the bottom surface S2 of the gate trench GT. The third gate insulating layer 115c may not overlap the first and second gate insulating layers 111c and 113c in the vertical direction (Z-direction) within the gate trench GT. In some implementations, the third gate insulating layer 115c may be disposed on the source region 107.

The thickness of the gate insulating layer 110c on the sidewall of the gate trench GT may be equal to the sum of the thicknesses of the first, second, and third gate insulating layers 111c, 113c, and 115c on the sidewalls of the gate trench GT. The thickness of the gate insulating layer 110c on the bottom surface of the gate trench GT may be the same as the thickness of the third gate insulating layer 115c on the bottom surface of the gate trench GT.

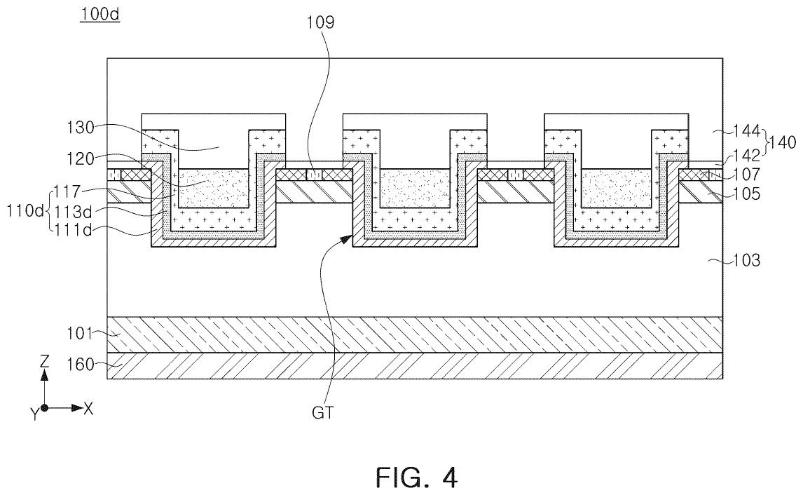

FIG. 4 is a cross-sectional view of an example of a power semiconductor device according to some implementations. In FIG. 4, the configuration of the power semiconductor device 100d, except for the gate insulating layers 110d, may be the same or similar to the configurations of the power semiconductor device 100 of FIG. 1A.

In FIG. 4, the gate insulating layers 110d may include a plurality of gate insulating layers 111d, 113d, and 117. The plurality of gate insulating layers 111d, 113d, and 117 may include a first gate insulating layer 111d sequentially disposed in the gate trench GT, a second gate insulating layer 113d on the first gate insulating layer 111d, and a fourth gate insulating layer 117 on the second gate insulating layer 113d.

The first and second gate insulating layers 111d and 113d may have a configuration corresponding to the first and second gate insulating layers 111 and 113 of FIG. 1A.

The fourth gate insulating layer 117 may be disposed on the second gate insulating layer 113d. The fourth gate insulating layer 117 may include a low-k material. The low-κ material may refer to a dielectric material having a lower dielectric constant than a silicon oxide film (SiO₂). The low-κ material may include, for example, fluorine-doped silicon dioxide, organosilicate glass, carbon-doped oxide, porous silicon dioxide, porous organosilicate glass, spin-on organic polymeric dielectric, or spin-on silicon based polymeric dielectric.

The fourth gate insulating layer 117 may be deposited using a deposition technique, such as chemical vapor deposition (CVD), plasma enhanced chemical deposition (PE-CVD), or spin on dielectric (SOD).

The dielectric constant of the second gate insulating layer 113d (hereinafter referred to as a second dielectric constant) may have a dielectric constant greater than the dielectric constants of the first and fourth gate insulating layers 111d and 117. The dielectric constant of the first gate insulating layer 111d may be greater than that of the fourth gate insulating layer 117.

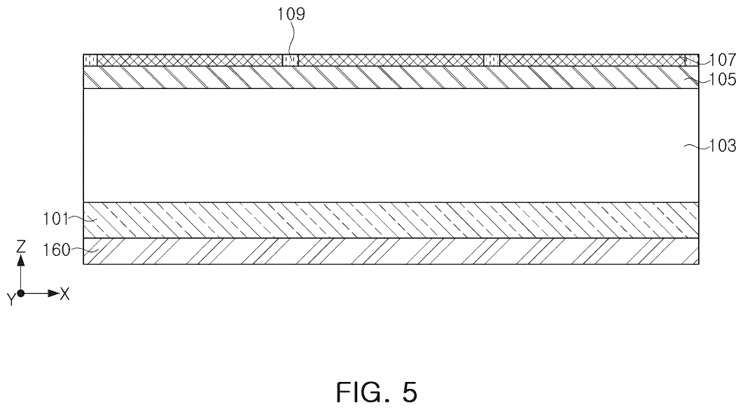

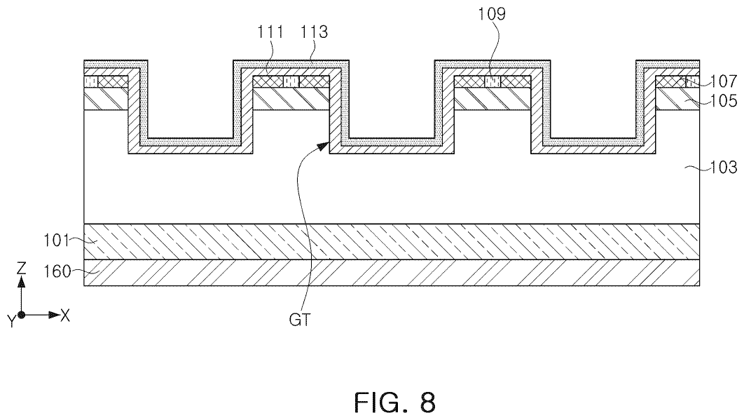

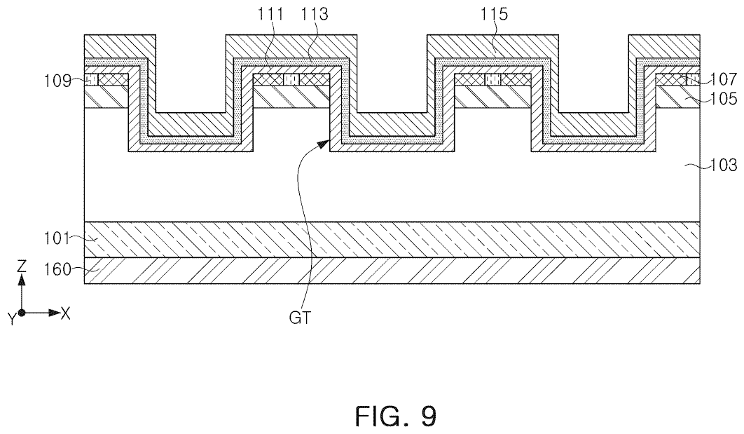

FIGS. 5 to 11 are diagrams illustrating an example of a method of manufacturing the power semiconductor device of FIG. 1A according to some implementations. In FIG. 5, a method of manufacturing a power semiconductor device may include forming a drift layer 103 on the substrate 101 and forming a well region 105, a source region 107, and well contact regions 109.

The substrate 101 may be provided as a SiC wafer, for example. The drift layer 103 may be formed by epitaxial growth from the substrate 101. The drift layer 103 may be formed to include first conductivity type impurities.

The well region 105, source region 107, and well contact regions 109 may be sequentially formed in the drift layer 103 by an ion implantation process. Second conductivity type impurities are implanted into the well region 105 and the well contact regions 109, and the source regions 107 are formed on the upper surface of the drift layer 103 to be spaced apart in the first direction (X-direction), and first conductivity type impurities may be implanted. After the ion implantation process, an annealing process may be performed at a high temperature, for example, about 1600° C. to about 1800° C.

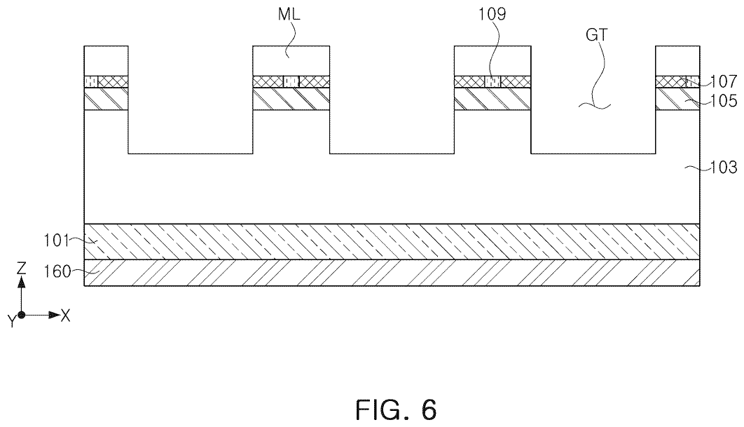

In FIG. 6, the method of manufacturing a power semiconductor device may include forming gate trenches GT by partially removing the source regions 107 and the well region 105.

By using the mask layer ML to partially expose the well region 105 between the source regions 107 and partially remove the well region 105 and the drift layer 103, the gate trenches GT may be formed. The mask layer ML may be, for example, a hard mask layer. The gate trenches GT may be formed to be spaced apart from each other along the first direction (X-direction). The gate trenches GT may be formed to completely penetrate the well region 105, and the drift layer 103 may be exposed through the bottom surface.

The formation process of the gate trench GT may include a dry etching process, a wet etching process, or a combination thereof.

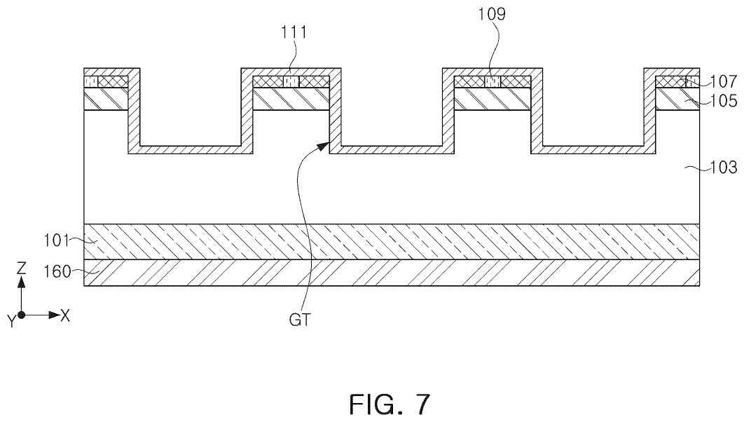

In FIGS. 7 to 9, a method of manufacturing a power semiconductor device may include sequentially forming the first and second gate insulating layers 111 and 113 and the third preliminary gate insulating layers 115P along the inner surfaces of the gate trenches GT.

The first gate insulating layer 111 may be formed on the inner surface of the gate trench GT by a thermal oxidation process.

The second gate insulating layer 113 may be formed on the first gate insulating layer 111 through a deposition process. For example, the second gate insulating layer 113 may be deposited by an atomic layer deposition (ALD) process.

The third gate insulating layer 115 may be formed on the second gate insulating layer 113 through a deposition process. For example, the third gate insulating layer 115 may be deposited by a chemical vapor deposition (CVD) process, a plasma enhanced chemical deposition (PE-CVD) process, or a spin on dielectric (SOD) process.

In some implementations, the third gate insulating layer 115 may be formed through multiple deposition processes. For example, after the third preliminary gate insulating layer is formed on the second gate insulating layer 113, an insulating material is further formed on the bottom surface of the gate trench GT. A third gate insulating layer 115 may be formed. Accordingly, the insulating material may be additionally formed only on the third preliminary gate insulating layer on the bottom surfaces of the gate trenches GT, and the insulating material may be deposited through the same or similar process as the deposition process of the third preliminary gate insulating layer.

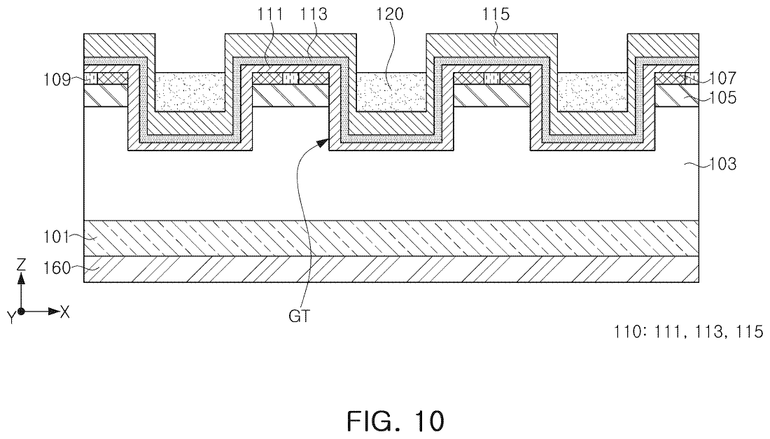

In FIG. 10, a method of manufacturing a power semiconductor device may include forming gate electrodes 120 on gate insulating layers 110. The gate electrodes 120 may be formed to be located only within the gate trenches GT. The gate electrodes 120 may be formed by depositing doped polycrystalline silicon and performing an etch-back process. In some implementations, the gate electrodes 120 may be formed by depositing a doped conductive metal material. For example, the gate electrodes 120 may include a semiconductor material, such as doped polycrystalline silicon, a metal nitride, such as titanium nitride (TiN), tantalum nitride (TaN), or tungsten nitride (WN), and/or a metallic material, such as aluminum (Al), tungsten (W), or molybdenum (Mo).

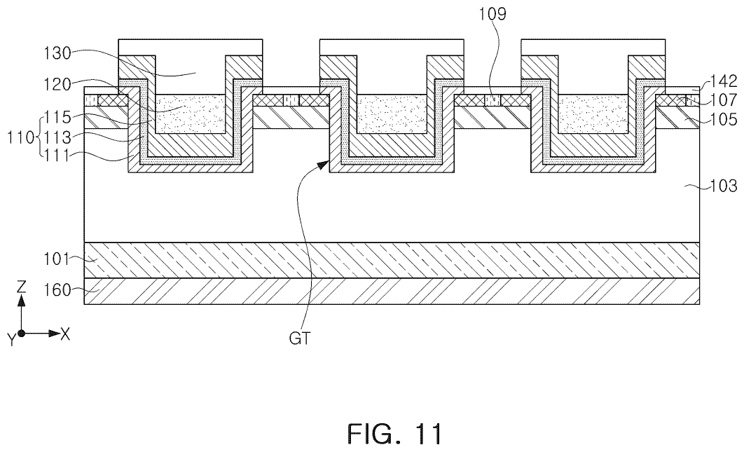

In FIG. 11, the method of manufacturing a power semiconductor device may include forming dielectric layers 130 and metal-semiconductor compound layers 142 covering the gate electrodes 120. The dielectric layers 130 may be deposited on the entire upper surface of the structure being manufactured and then partially removed through an etching process to expose a portion of each of the source regions 107 and well regions 105. For example, the dielectric layers 130 may be formed by being patterned together with the gate insulating layers 110. However, the present disclosure is not limited thereto, and in some implementations, the gate insulating layers 110 may be patterned in a separate process. The dielectric layer 130 may be formed to cover the upper surfaces of the gate electrode 120 and the gate insulating layers 110 and expose portions of the well region 105 and the source region 107.

Metal-semiconductor compound layers 142 may be formed on the exposed well region 105 and source region 107. The metal-semiconductor compound layers 142 may be formed through a silicidation process.

Next, in FIG. 1A, a conductive layer 144 may be formed on the metal-semiconductor compound layers 142, and a drain electrode 160 may be formed on the lower surface of the substrate 101. The conductive layer 144 may be formed to cover the metal-semiconductor compound layers 142 and the dielectric layers 130, thereby forming the source electrode 140.

The drain electrode 160 may be formed by depositing a metal material on the lower surface of the substrate 101. In some implementations, drain electrode 160 may be formed in another process step. Accordingly, the power semiconductor device 100 of FIG. 1A may be manufactured.

As set forth above, a power semiconductor device include a plurality of gate insulating layers disposed between the gate electrode and the well region to control channel mobility and switching speed, and the gate insulating layers may have a relatively thin thickness on side surfaces of the gate trench and may have a relatively thick thickness on the bottom surface of the gate trench. Accordingly, the electrical characteristics of the power semiconductor device may be improved.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A power semiconductor device comprising:
a substrate of a first conductivity type;
a drift layer of a first conductivity type on the substrate;
a well region of a second conductivity type on the drift layer;
a source region of the first conductivity type on the well region;
a gate electrode disposed in a gate trench extending into the source region and the well region;
a first gate insulating layer, a second gate insulating layer, and a third gate insulating layer disposed between the well region and the gate electrode;
a dielectric layer on the gate electrode; and
a drain electrode on a lower surface of the substrate,
wherein the first gate insulating layer has a first dielectric constant,
wherein the second gate insulating layer has a second dielectric constant greater than the first dielectric constant, and
wherein the third gate insulating layer has a first thickness on a bottom surface of the gate trench and a second thickness, less than the first thickness, on a sidewall of the gate trench.

2. The power semiconductor device of claim 1,
wherein the first gate insulating layer contacts the well region and the source region within the gate trench,
wherein the second gate insulating layer is on the first gate insulating layer, and
wherein the third gate insulating layer is disposed on the second gate insulating layer and contacts a side surface and a bottom surface of the gate electrode.

3. The power semiconductor device of claim 1, wherein the first gate insulating layer has a third thickness less than the first thickness on the bottom surface of the gate trench.

4. The power semiconductor device of claim 1,
wherein a lower surface of the third gate insulating layer corresponds to a surface profile of the gate trench, and
wherein an upper surface of the third gate insulating layer includes a side surface facing the sidewall of the gate trench and a flat surface extending from the side surface within the gate trench.

5. The power semiconductor device of claim 1, wherein the gate electrode does not overlap the second gate insulating layer in a vertical direction.

6. The power semiconductor device of claim 5, wherein the third gate insulating layer is in contact with the first gate insulating layer on the bottom surface of the gate trench.

7. The power semiconductor device of claim 1, wherein the gate electrode does not overlap the first gate insulating layer and the second gate insulating layer in a vertical direction.

8. The power semiconductor device of claim 7, wherein the third gate insulating layer contacts the drift layer on the bottom surface of the gate trench.

9. The power semiconductor device of claim 1, wherein the third gate insulating layer has a third dielectric constant less than the second dielectric constant.

10. The power semiconductor device of claim 1, wherein the third gate insulating layer has a third dielectric constant less than the first dielectric constant.

11. The power semiconductor device of claim 1, wherein the third gate insulating layer includes the same insulating material as the first gate insulating layer.

12. The power semiconductor device of claim 1,
wherein the first gate insulating layer, the second gate insulating layer, and the third gate insulating layer extend onto the source region, and
wherein an upper surface of the third gate insulating layer on the source region is disposed at a level higher than a level of an upper surface of the gate electrode.

13. The power semiconductor device of claim 1, wherein the substrate, the drift layer, and the well region comprise silicon carbide (SiC).

14. A power semiconductor device comprising:
a substrate of a first conductivity type;
a drift layer of a first conductivity type on the substrate;
a well region of a second conductivity type on the drift layer;
a source region of the first conductivity type on the well region;
a gate electrode in a gate trench extending into the source region and the well region;
gate insulating layers including a first gate insulating layer, a second gate insulating layer, and a third gate insulating layer sequentially disposed between the well region and the gate electrode;
a dielectric layer on the gate electrode; and
a drain electrode on a lower surface of the substrate,
wherein the second gate insulating layer includes an insulating material different from insulating materials of the first gate insulating layer and the third gate insulating layer, and
wherein the gate insulating layers have a first thickness on a bottom surface of the gate trench and a second thickness, less than the first thickness, on a sidewall of the gate trench.

15. The power semiconductor device of claim 14, wherein a thickness of the third gate insulating layer on the bottom surface of the gate trench is thicker than a thickness of the first gate insulating layer on the bottom surface of the gate trench and a thickness of the second gate insulating layer on the bottom surface of the gate trench.

16. The power semiconductor device of claim 14,
wherein the gate insulating layers extend onto the source region, and
wherein a thickness of the third gate insulating layer on the source region is less than a thickness of the gate insulating layer on the bottom surface of the gate trench and is greater than a thickness of the third gate insulating layer on the sidewall of the gate trench.

17. The power semiconductor device of claim 14, wherein the second gate insulating layer has a dielectric constant greater than a dielectric constant of the first gate insulating layer and a dielectric constant of the third gate insulating layer.

18. The power semiconductor device of claim 14, wherein a thickness of the first gate insulating layer on the bottom surface of the gate trench is less than a thickness of the first gate insulating layer on the sidewall of the gate trench.

19. A power semiconductor device comprising:
a substrate of a first conductivity type;
a drift layer of a first conductivity type on the substrate;
a well region of a second conductivity type on the drift layer;
a source region of the first conductivity type on the well region;
a gate electrode in a gate trench extending into the source region and the well region;
gate insulating layers disposed between the well region and the gate electrode, the gate insulating layers having a first thickness on a bottom surface of the gate trench and a second thickness, less than the first thickness, on a sidewall of the gate trench;
a dielectric layer on the gate electrode; and
a drain electrode on a lower surface of the substrate,
wherein the gate insulating layers includes
a first gate insulating layer on the sidewall of the gate trench;
a second gate insulating layer on the first gate insulating layer; and
a third gate insulating layer disposed on the second gate insulating layer and in contact with the gate electrode, and
wherein the third gate insulating layer has a third thickness on the bottom surface of the gate trench and a fourth thickness less than the third thickness on the sidewall of the gate trench.

20. The power semiconductor device of claim 19, wherein the gate electrode has a first width in a horizontal direction and a second width narrower than the first width in a vertical direction.
